(19) United States
(12) Patent Application Publication
(10) Pub. No.: US 2017/0256453 A1
(43) Pub. Date: Sep. 7, 2017

(54) METHOD OF MANUFACTURING SEMICONDUCTOR PACKAGE AND SEMICONDUCTOR PACKAGE

(71) Applicant: J-DEVICES CORPORATION, Oita (JP)

(72) Inventors: Takahiro YADA, Ishikawa (JP); Katsushi YOSHIMITSU, Ishikawa (JP)

(21) Appl. No.: 15/409,631

(22) Filed: Jan. 19, 2017

(30) Foreign Application Priority Data
Mar. 7, 2016 (JP) 2016-043519

(51) Int. Cl. H01L 21/78; H01L 21/306; H01L 21/56; H01L 21/304; H01L 25/065; H01L 23/31

(52) U.S. Cl. CPC H01L 21/78; H01L 25/0655; H01L 23/3114; H01L 21/56; H01L 21/3043; H01L 21/30604

(57) ABSTRACT

A manufacturing method of a semiconductor package which improves productivity and can manufacture high-quality semiconductor packages is provided. The manufacturing method of a semiconductor package includes arranging a plurality of semiconductor devices at intervals on a first surface side of a support substrate, forming a first insulating resin layer forming wiring connected to each of the plurality of semiconductor devices and embeds the plurality of semiconductor devices, cutting from the first surface side in areas between the plurality of semiconductor devices, forming a first groove portion penetrating the first insulating resin layer and exposing the support substrate, and dividing individual semiconductor packages by forming a resist pattern having openings arranged corresponding to the first groove portion on a second surface on the opposite side of the first surface, etching the openings from the second surface side, and forming a second groove portion on the second surface side

### CROSS REFERENCE TO RELATED APPLICATIONS

This application is based on and claims the benefit of priority from the prior Japanese Patent Application No. 2016-043519, filed on Mar. 7, 2016, the entire contents of which are incorporate herein by reference.

### FIELD

The present invention relates to a manufacturing method of a semiconductor package. Especially, the present invention relates to a manufacturing method of a semiconductor package that has a metal substrate.

### BACKGROUND

Conventionally, a semiconductor structure in which semiconductor devices such as IC chips are mounted on top of support substrates in electronic devices such as mobile phones, smart phones, etc. is known (e.g. Japanese Laid-Open Patent Publication No. 2010-278334). In semiconductor packages such as this typically have a structure in which semiconductor devices such as IC chips and memory are attached on top of a support substrate with an adhesive layer and the semiconductor device is covered with a sealing body (sealing resin materials) which protects the semiconductor device.

Print substrates, ceramic substrates, and various other substrates may be used as the support substrate in the semiconductor package. Especially in recent years, development of semiconductor packages that use a metal substrate has been advancing. Semiconductor packages with a semiconductor device mounted on top of a metal substrate and fanned out by rewiring have advantages such as excellent electromagnetic shielding properties and thermal qualities, and have attracted attention as highly reliable semiconductor packages. Semiconductor packages such as this also have the advantage of having a high degree of freedom for package design.

When semiconductor devices are mounted on a support substrate, it is possible to manufacture multiple semiconductor packages in the same process by mounting a plurality of semiconductor devices on a large support substrate. In this case, the plurality of semiconductor packages formed on the support substrate are separated after the manufacturing process and the individual semiconductor packages are completed. Semiconductor package structures with semiconductor devices mounted on a support substrate such as this also have the advantage of having a high-volume production rate.

### SUMMARY

A manufacturing method of a semiconductor package according to one embodiment of the present invention includes arranging a plurality of semiconductor devices at intervals on a first surface side of a support substrate, forming a first insulating resin layer forming wiring connected to each of the plurality of semiconductor devices and embeds the plurality of semiconductor devices, cutting from the first surface side in areas between the plurality of semiconductor devices, forming a first groove portion penetrating the first insulating resin layer and exposing the support substrate, and dividing individual semiconductor packages by forming a resist pattern having openings arranged corresponding to the first groove portion on a second surface on the opposite side of the first surface, etching the openings from the second surface side, and forming a second groove portion on the second surface side.

A manufacturing method of a semiconductor package according to one embodiment of the present invention includes forming a bottom groove portion on a second surface on the opposite side of a first surface in areas between a plurality of semiconductor devices arranged at intervals on a first surface side of a support substrate, arranging the plurality of semiconductor devices at intervals on the first surface side of the support substrate, forming an insulating resin layer forming wiring connected to each of the plurality of semiconductor devices and embeds the plurality of semiconductor devices, and dividing the plurality of semiconductor devices by cutting with a mechanical process from the first surface side along a boundary.

### BRIEF DESCRIPTION OF THE DRAWINGS

FIG. 1 is a cross-sectional view explaining a structure of a semiconductor package according to one embodiment of the present invention;

FIG. 2A is a cross-sectional view explaining the manufacturing method of the semiconductor package according to one embodiment of the present invention;

FIG. 2B is a cross-sectional view explaining the manufacturing method of the semiconductor package according to one embodiment of the present invention;

FIG. 2C is a cross-sectional view explaining the manufacturing method of the semiconductor package according to one embodiment of the present invention;

FIG. 2D is a cross-sectional view explaining the manufacturing method of the semiconductor package according to one embodiment of the present invention;

FIG. 2E is a cross-sectional view explaining the manufacturing method of the semiconductor package according to one embodiment of the present invention;

FIG. 2F is a cross-sectional view explaining the manufacturing method of the semiconductor package according to one embodiment of the present invention;

FIG. 2G is a cross-sectional view explaining the manufacturing method of the semiconductor package according to one embodiment of the present invention;

FIG. 2H is a cross-sectional view explaining the manufacturing method of the semiconductor package according to a modification example of one embodiment of the present invention;

FIG. 3A is a cross-sectional view explaining the manufacturing method of the semiconductor package according to one embodiment of the present invention;

FIG. 3B is a cross-sectional view explaining the manufacturing method of the semiconductor package according to one embodiment of the present invention;

FIG. 3C is a cross-sectional view explaining the manufacturing method of the semiconductor package according to one embodiment of the present invention;

FIG. 3D is a cross-sectional view explaining the manufacturing method of the semiconductor package according to one embodiment of the present invention;

FIG. 4A is a cross-sectional view explaining the manufacturing method of the semiconductor package according to one embodiment of the present invention;

FIG. 4B is a cross-sectional view explaining the manufacturing method of the semiconductor package according to one embodiment of the present invention;

FIG. 4C is a cross-sectional view explaining the manufacturing method of the semiconductor package according to one embodiment of the present invention;

FIG. 4D is a cross-sectional view explaining the manufacturing method of the semiconductor package according to one embodiment of the present invention;

FIG. 4E is a cross-sectional view explaining the manufacturing method of the semiconductor package according to one embodiment of the present invention; and

FIG. 4F is a cross-sectional view explaining the manufacturing method of the semiconductor package according to a modification example of one embodiment of the present invention.

### DESCRIPTION OF THE EMBODIMENTS

Hereinafter, the embodiments of the present invention will be explained while referencing the drawings. However, the present invention may be implemented in many different ways, therefore interpretation should not be limited to the content exemplified in the embodiments below. In order to provide a clearer explanation, some components of the drawings such as the width, thickness, shape, etc. of each part are represented schematically. These drawings are merely examples and do not limit the interpretation of the present invention. In this specification and each of the drawings, elements similar to previously described elements are marked with the same symbols and detailed descriptions are omitted accordingly.

In this specification, when certain components and areas are described as being “above” or “below” other components or areas, as long as there are no limitations, it does not necessarily mean they are directly above or below. This description includes cases in which a component or area is located higher or lower than another component or area. In other words, other components or areas are located between the component being described and the component above or below.

### Embodiment 1

### [Structure of Semiconductor Package 100]

The structure of the semiconductor package 100 according to the present embodiment will be described while referencing the drawings.

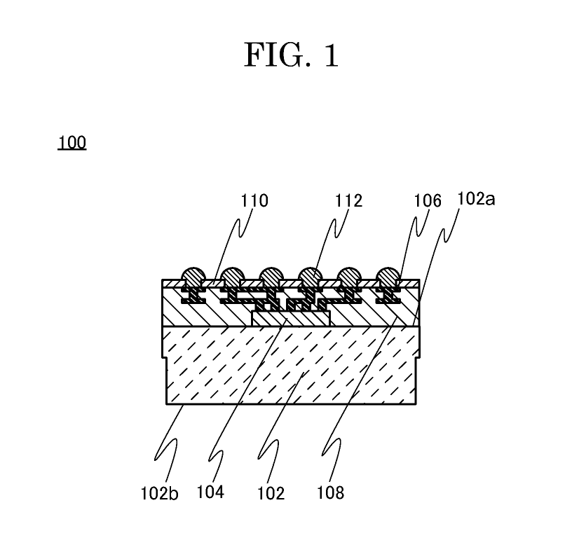

FIG. 1 is a cross-sectional view describing the structure of the semiconductor package 100 according to the present embodiment. The semiconductor package 100 according to the present embodiment has a support substrate 102, a semiconductor device 104, wiring 106, a first insulating resin layer 108, a second insulating resin layer 110, and a plurality of solder balls 112.

The support substrate 102 preferably has a thickness of more than 200 μm and less than 500 μm. In the present embodiment, the support substrate 102 has an assumed thickness of 300 μm.

In the present embodiment, an end portion of a second surface 102b of the support substrate 102 is located further inward than an end portion of a first surface 102a of the support substrate 102.

A metal substrate may be used as the support substrate 102. The metal substrate may be formed of metal materials such as stainless steel (SUS), copper (Cu), aluminum (Al), titanium (Ti), and the like.

Other than a metal substrate, semiconductor substrates such as silicon substrates, silicon carbide substrates, or compound semiconductor substrates, and insulating substrates such as glass substrates, quartz substrates, sapphire substrates, or resin substrates may be used as the support substrate 102.

The semiconductor device 104 is located on the first surface side 102a of the support substrate 102. The semiconductor device 104 is fixed to the first surface side 102a with an adhesive (not shown). Epoxy resin, polyimide resin, and the like may be used as the adhesive. An external terminal (not shown) connected to an electronic circuit in the semiconductor device 104 is placed on the upper portion of the semiconductor device 104. In the present embodiment, the semiconductor package 100 is shown to have one semiconductor device 104. However, the semiconductor package according to the present invention is not limited to this, as long as there is at least one semiconductor device 104.

The semiconductor device 104 may be a Central Processing Unit (CPU), memory, Micro Electro Mechanical Systems (MEMS), and the like.

The first insulating resin layer 108 is located above the support substrate 102 so as to embed the semiconductor device 104. An opening that reaches the external terminal of the semiconductor device 104 is provided in the first insulating resin layer 108.

The first insulating resin layer 108 may be formed of organic resin. For example, polyimide, epoxy resin, polyimide resin, benzocyclobutene resin, polyamide, phenol resin, silicon resin, fluorine resin, liquid crystal polymer, polyamide-imide, polybenzoxazole, cyanate resin, aramid, polyolefin, polyester, BT resin, FR-4, FR-5, polyacetal, polybutylene terephthalate, syndiotactic polystyrene, Polyphenylene sulfide, polyether ether ketone, polyether nitrile, polycarbonate, polyphenylene ether polysulfone, polyethersulfone, polyarylate, polyetherimide, and the like may be used.

The wiring 106 is connected to the external connection terminal on the upper portion of the semiconductor device 104 via the above-mentioned opening in the first insulating resin layer 108. The wiring 106 is electrically and physically separated from the support substrate 102 by the first insulating resin layer 108.

Metals such as copper (Cu), gold (Au), silver (Ag), platinum (Pt), rhodium (Rh), tin (Sn), aluminum (Al), nickel (Ni), palladium (Pd), chromium (Cr), and the like as well as alloys that contain these metals may be used as materials for the wiring 106. Further, the wiring 106 may have a laminated structure containing multiple materials chosen from the above-mentioned materials for each layer.

A second insulating resin layer 110 is arranged to cover the first insulating resin layer 108. A plurality of openings 110a are provided in the second insulating resin layer 110. Each of the plurality of openings 110a reaches the wiring 106. In other words, the plurality of openings 110a are provided in order to expose the wiring 106. The second insulating resin layer 110 creates a sufficient gap between the wiring 106 and the solder ball 112 in order to prevent conduction between the wiring 106 and the solder ball 112.

The second insulating resin layer 110 may be formed of the same materials used to form the first insulating resin layer 108.

The solder ball 112 is located inside and above the openings 110a on the second insulating resin layer 110 and is connected to the wiring 106. The top surface of the solder ball 112 protrudes from the top surface of the second insulating resin layer 110 to above the second insulating resin layer 110. The protruding portion of the solder ball 112 has a convex shape which curves upward.

In the following description, the first insulating resin layer 108 and the second insulating resin layer 110 will be collectively referred to as the insulating resin layer 111.

The solder ball 112 may be a spherical object formed of alloys of Sn and small amounts of Ag, Cu, Ni, bismuth (Bi), or zinc (Zn). General conducting particles may be used in addition to the solder ball 112 as well. For example, particles formed of a conductive film in the periphery of a particle shaped resin may be used as conducting particles.

### [Manufacturing Method of Semiconductor Package 100]

The manufacturing method of the semiconductor package 100 according to the present embodiment will be explained while referencing the drawings.

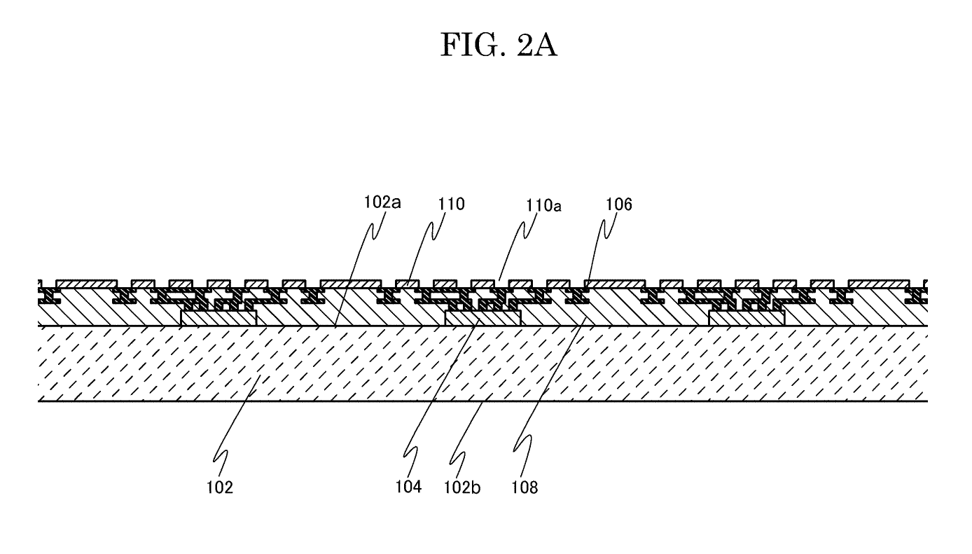

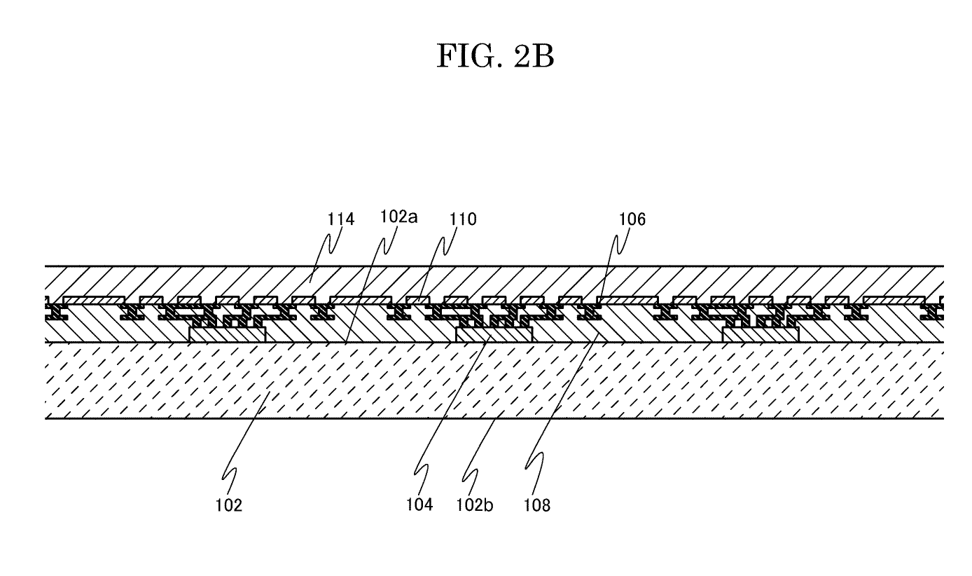

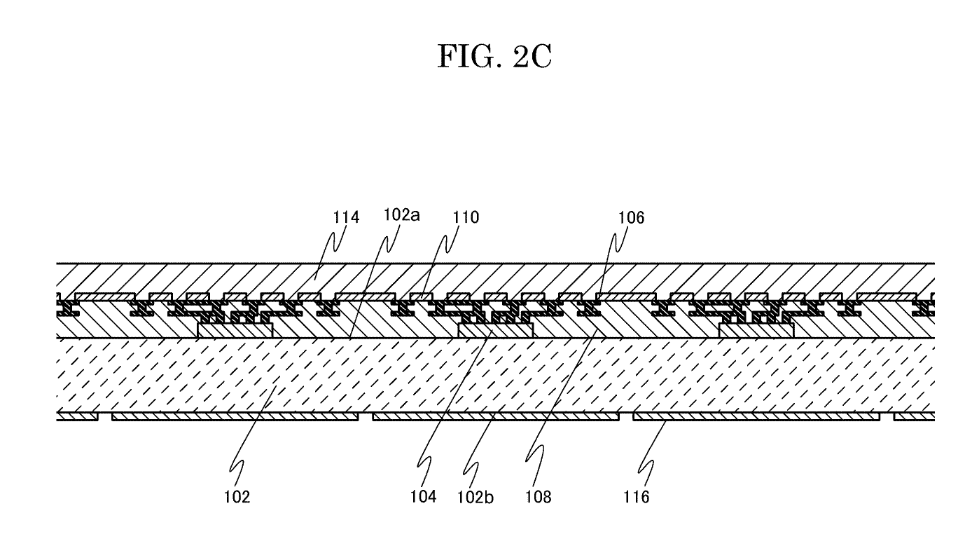

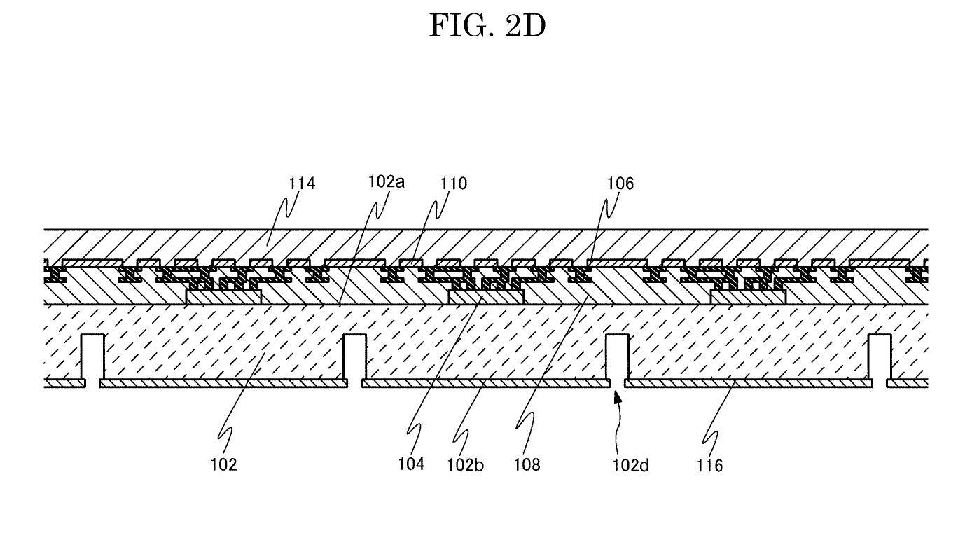

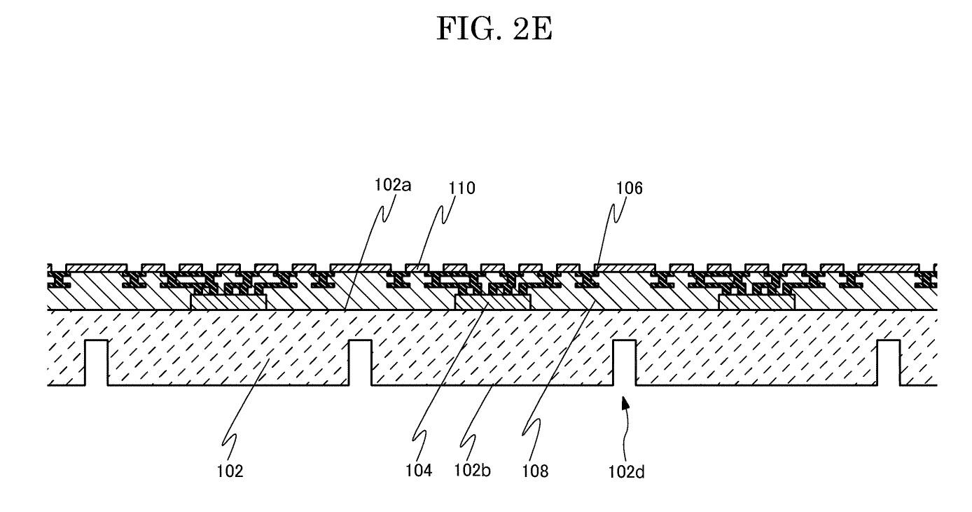

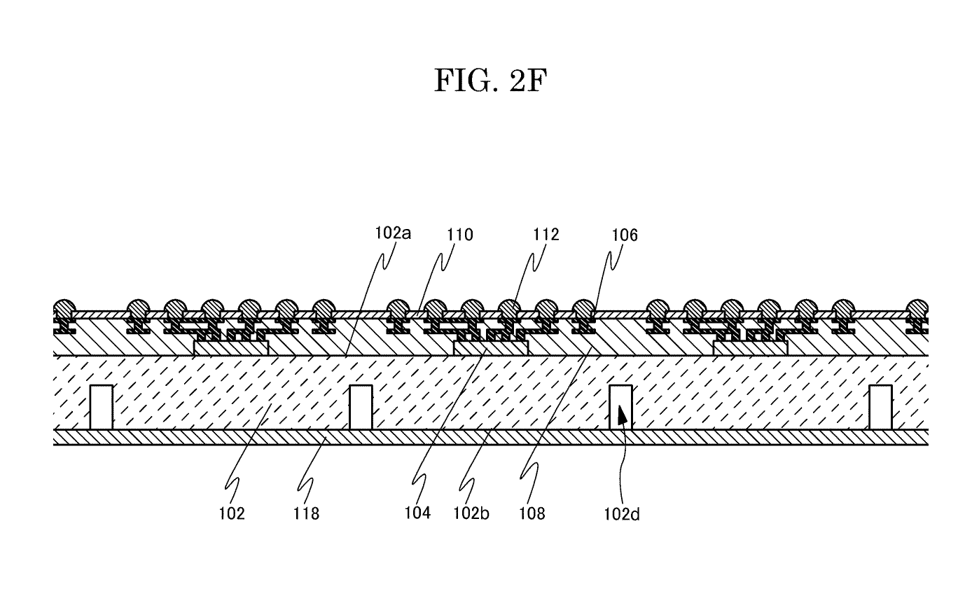

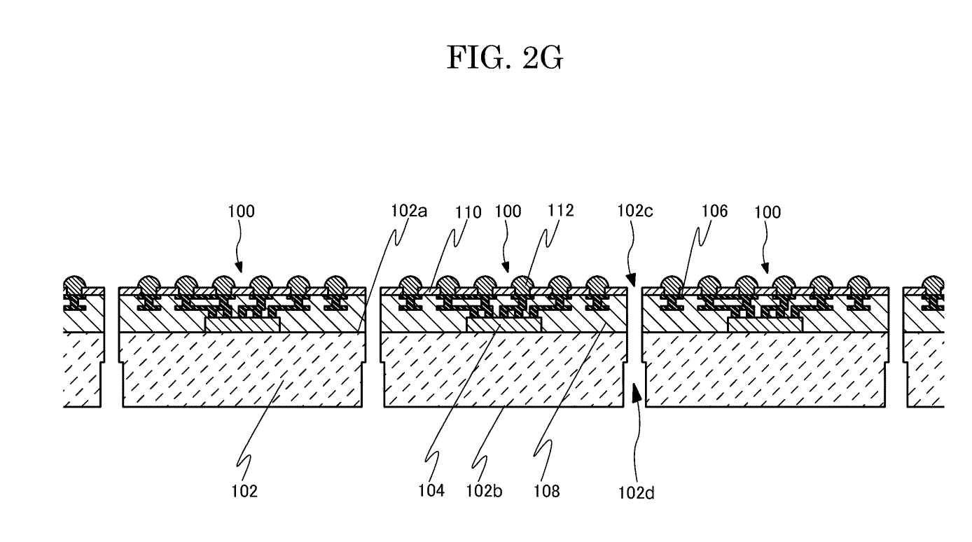

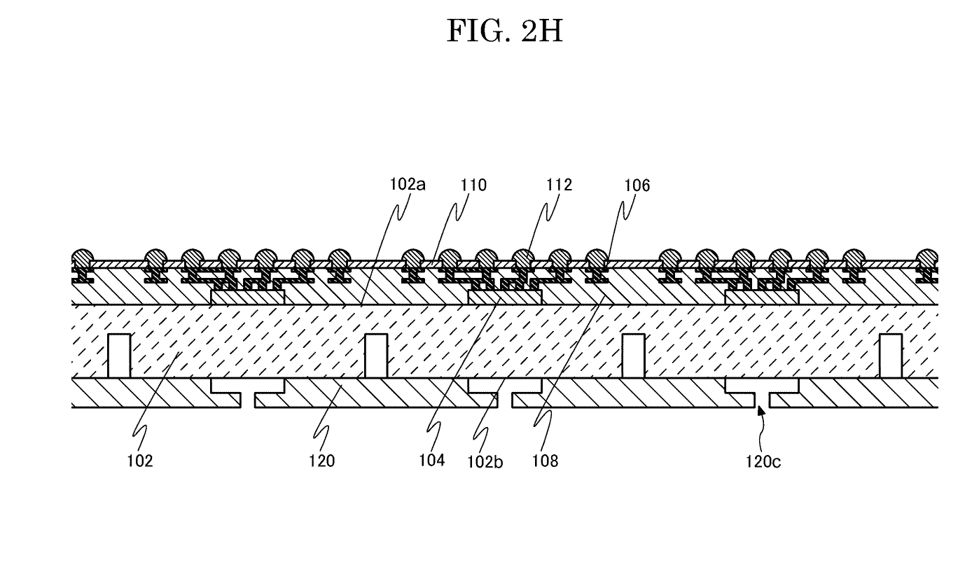

FIG. 2A to FIG. 2G are cross-sectional views explaining the manufacturing method of the semiconductor package 100 according to the present embodiment.

FIG. 2A is a cross-sectional view of the manufacturing method of the semiconductor package 100 in a state in which the second insulating resin layer 110 has been formed.

The manufacturing process up to this point will be simply explained. A plurality of semiconductor devices 104 are arranged at intervals on the first surface side 102a of the support substrate. The semiconductor devices 104 are fixed to the first surface side 102a of the support substrate 102 with an adhesive (not shown). The materials previously explained may be used as the adhesive.

Next, a first insulating layer 108 that forms wiring connected to each of the plurality of semiconductor devices 104 and embeds the plurality of semiconductor devices is formed on the first surface side 102a of the support substrate 102.

Next, the separation process of the semiconductor packages 100 in the state shown in FIG. 2A into individual semiconductor packages 100 will be described in detail. The process for separating individual semiconductor packages 100 includes the following step (a) and step (b).

Step (a): Cutting is performed from a first surface to form a first groove portion 102c in the areas between the plurality of semiconductor devices. The first groove portion 102c penetrates the insulating resin layer 111, exposing the support substrate 102.
Step (b): A resist pattern having openings arranged corresponding to the first groove portion 102c is formed on a second surface on the opposite side of the first surface, the openings are etched from the second surface side, and a second groove portion 102d is formed on the second surface side.

The cutting process may be carried out by using a dicing saw. In a cutting process that uses a dicing saw, a circular dicing blade made of diamond is rotated at high speed and cuts while purified water is used to cool and wash away cutting waste. Another method that may be applied is a punching process that uses a metal mold. In either case, it is preferable that step (a) be a mechanical process so that the insulating resin layer 111 and the support substrate 102, which are formed of different materials, may be cut in the same process.

The etching process may be a wet etching process using a chemical solution that can etch components of the support substrate, or a dry etching process using an etching gas. From an etching speed perspective, wet etching is preferred. Using etching, an entire surface of the support substrate may be processed at once.

In this way, according to the present embodiment, productivity increases and manufacturing cost decreases when semiconductor packages with different structures are separated by a combination of mechanical and chemical processes. Namely, the amount of cutting using a chemical process is lower if the insulating layer 111 and a portion of the support substrate are cut in a mechanical process. In addition, when a portion of the support substrate is etched in a chemical process, less burden is put on the equipment used in the mechanical process.

The individual semiconductor packages 100 are separated by a combination of these two steps. The order in which step (a) and step (b) are carried out is arbitrary. In the present embodiment, an example in which step (b) takes place before step (a) is shown.

First, before the above-mentioned step (b) takes place, from the state shown in FIG. 2A, a protective film 114 is applied to the first surface 102a of the support substrate 102 (FIG. 2B). In this way, the wiring 106 formed above the support substrate 102 is protected during the process in step (b).

The protective film 114 is made of materials that are resistant to chemicals used in the etching process included in subsequent step (b). This material may be an acrylic dry film resist, and the like.

Next, step (b) is performed. Namely, on the second surface on the opposite side of the first surface, a resist pattern having openings in the areas between the plurality of semiconductor devices is formed, the openings are etched from the second surface side, and a second groove portion 102d is formed on the second surface side.

In the present embodiment, a resist pattern 116 is formed by photolithography on the second surface side 102b of the support substrate 102 (FIG. 2C).

The support substrate 102 is etched in a wet etching process using the resist pattern 116 as a mask. The second groove portion 102d having a bottom is formed without etching as far as the first surface 102a of the support substrate 102 (FIG. 2D). The depth of the groove portion 102d from the second surface 102b of the support substrate 102 is preferably about ⅔ of the thickness of the support substrate 102. In the present embodiment, since the thickness of the support substrate is 300 μm, it is preferred that about 200 μm is etched, leaving about 100 μm of the support substrate 102 from the first surface 102a.

If the second groove portion 102d having a bottom is deeper than this, the etching time is prolonged and productivity worsens. Additionally, problems with handling arise. If the second groove portion 102d having a bottom is shallower than this, the dicing blade in the later step (a) wears out faster and manufacturing costs increase.

As is shown in FIG. 2D, in the etching process of the second surface, the second groove portion 102d extends into an area more expansive than the region exposed by the resist pattern 116. This is because side etching takes place in the etching step.

After the second surface side 102b of the support substrate 102 is etched, the protective film 114 and the resist pattern 116 are removed (FIG. 2E).

Next, the solder balls 112 are arranged corresponding to the openings 110a of the second insulating resin layer 110. In the present embodiment, an example is shown in which one solder ball 112 is arranged corresponding to one opening 110a. However, the present invention is not limited to this, and multiple solder balls 112 may be arranged corresponding to one opening 110a.

Next, step (a) takes place. Namely, in the areas between the plurality of semiconductor devices, cutting is performed from the first surface side, forming the first groove portion 102c which penetrates the insulating resin layer 111 and exposes the support substrate.

In the present embodiment, after the step in which the second surface 102b of the support substrate 102 is cut by a wet etching process (step (b)) and before step (a), a support member is put in place on the second surface side 102b of the support substrate 102. In the present embodiment, dicing tape 118 is used as the support member and is applied to the second surface side 102b (FIG. 2F).

Since the second groove portion 102d having a bottom is formed on the support substrate 102 by step (b), the structure shown in FIG. 2E is not mechanically strong. Accordingly, the support substrate 102 is held in place by the support member during the dicing process, as in the present embodiment.

From here, the insulating resin layer 111 and a portion of the support substrate 102 are cut at the same time by a dicing saw. Cutting is performed by rotating the dicing blade at high speed while cooling and washing away cutting waste with purified water. In this way, the individual semiconductor packages 100 are separated (FIG. 2G). The semiconductor package 100 shown in FIG. 1 is obtained through the above process.

The manufacturing method of the semiconductor package 100 according to the present embodiment was described above. According to the manufacturing method of the semiconductor package 100 according to the present embodiment, the semiconductor packages 100 are separated without cutting by conventional laser dicing, by a combination of a wet etching process and a cutting process using a dicing saw. As a result, especially in the manufacturing of small semiconductor packages, production speed improves and cost decreases. Particularly when the support substrate 102 is a metal substrate, the common problem of metal burrs appearing on the cut surface may be prevented, thus producing a high-quality semiconductor package.

However, the conventional process of separation using a laser dicing device has size constraints, and is ill-suited for the production of small semiconductor packages. On the other hand, in the conventional separation process using a blade dicing device, even though the insulating resin layer and the metal support substrate are cut at the same time along the dicing line, the production speed is notably slower. Even in terms of quality, the occurrence of metal burrs on the cut surface is a problem.

When, for example, separation is performed using only wet etching, it is necessary to have individual etching processes for the insulating resin layer 111 and the support substrate 102. Because of this, slower processing speed is a concern, as it is necessary to etch the support substrate en bloc. Further, manufacturing costs increase as different chemicals are needed for each etching process.

Conversely, when separation is done by cutting the insulating resin layer 111 and the support substrate 102 at the same time using a dicing saw, for example, a lower throughput of the semiconductor packages due to the common problem of metal burrs is a concern. Further, since the support substrate is cut en bloc, the dicing blade wears out faster, which increases manufacturing costs.

According to the present embodiment, since separation is performed by combining a wet etching process and a cutting process using a dicing saw, the problems mentioned above do not occur, thus lowering manufacturing costs and increasing production speed.

### Modification Example 1

In a modification example of the manufacturing method of the semiconductor package 100 according to the present embodiment, a dicing jig 120 may be used instead of the dicing tape 118 shown in FIG. 2H. In the dicing jig, an adsorption hole 120c is provided in a position corresponding to each of the semiconductor packages 100 being separated. The support substrate 102 is held in place by vacuuming from the adsorption holes 120c, and step (a) may take place.

### Embodiment 2

### [Manufacturing Method of Semiconductor Package 200]

The manufacturing method of the semiconductor package 200 according to the present embodiment will be explained while referencing the drawings. The structure of the semiconductor package 200 according to the present embodiment is the same as the structure of the semiconductor package 100 in embodiment 1, therefore a description is omitted.

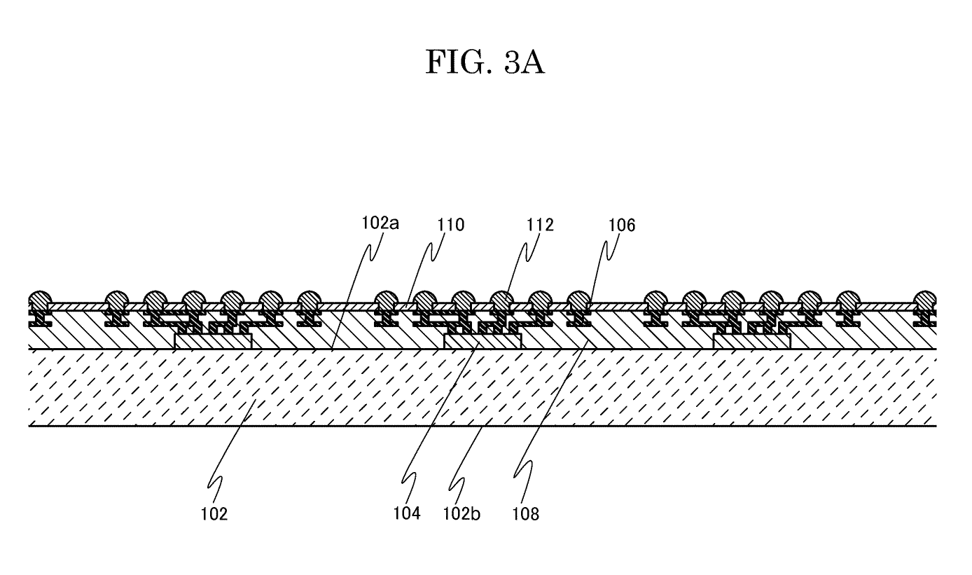

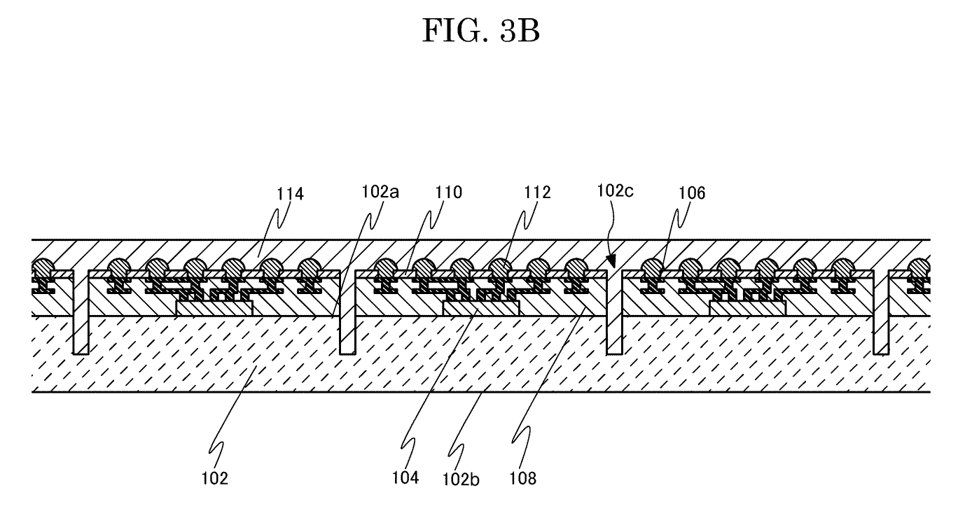

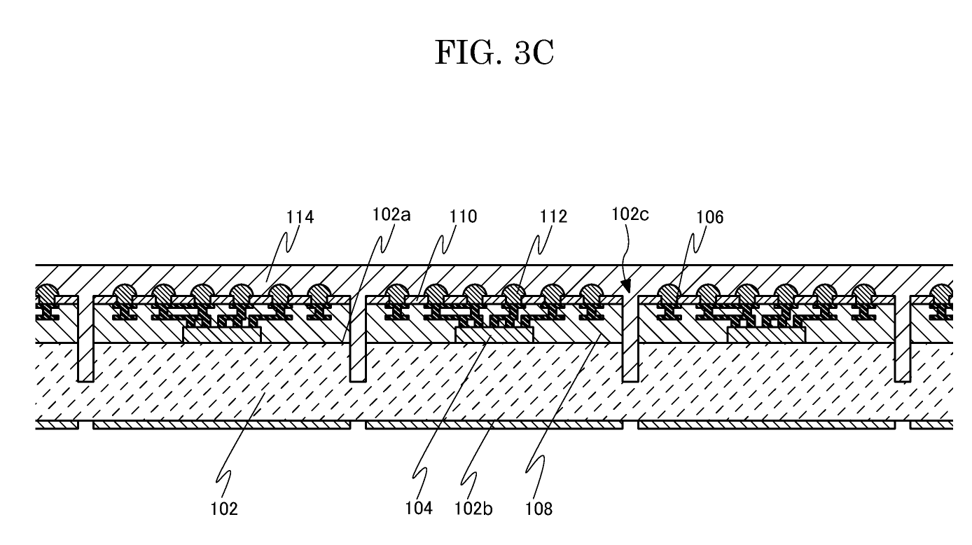

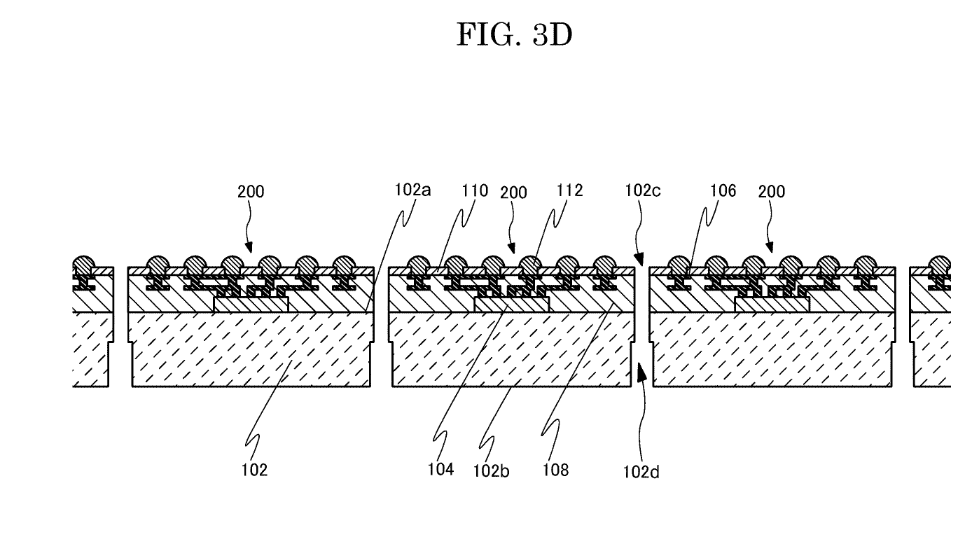

FIG. 3A through 3D are cross-sectional views explaining the manufacturing method of the semiconductor package 200 according to the present embodiment.

The order of step (a) and step (b) in the separation process in the manufacturing method of the semiconductor package 200 according to the present embodiment is different to that of the manufacturing method of the semiconductor package 100 in embodiment 1. Namely, in the present embodiment, step (a) is conducted before step (b).

FIG. 3A is a cross-sectional view of the step in which the solder ball 112 has been formed in the manufacturing method of the semiconductor package 200. At this point, the solder balls 112 have been formed above the second insulating resin layer 110 by the process described above for the structure shown in FIG. 2A.

Next, step (a) takes place. Namely, cutting is performed from the first surface side in the areas between the plurality of semiconductor devices, forming the first groove portion 102c that penetrates the insulating resin layer 111, and exposing the support substrate. The insulating resin layer 111 and a portion of the support substrate 102 are cut at the same time.

The first groove portion 102c having a bottom is formed without etching as far as the second surface 102b of the support substrate 102. Preferably, the depth of the first groove portion 102c from the second surface 102b of the support substrate 102 is about ⅓ of the thickness of the support substrate 102. In the present embodiment, the thickness of the support substrate is 300 μm, therefore 100 μm is preferably cut leaving 200 μm of the support substrate 102 from the second surface 102a.

If the first groove portion 102c having a bottom is too shallow, the etching time in the following step (b) is prolonged and productivity worsens. Handling problems also occur. If the first groove portion 102c having a bottom is too deep, the dicing blade wears out faster, and manufacturing costs increase.

Next, before step (b) takes place, a protective film 114 is applied to the first surface side 102a of the support substrate 102 (FIG. 3B). In this way, the wiring 106 formed above the support substrate 102 is protected during step (b).

Next, step (b) is conducted. Namely, a resist pattern having openings arranged corresponding to the first groove portion 102c is formed on the second surface on the opposite side of the first surface, the openings are etched from the second surface side, and the second groove portion 102d is formed on the second surface side.

In the present embodiment, in the same way as in embodiment 1, the resist pattern 116 is formed by photolithography on the second surface side 102b of the support substrate 102 (FIG. 3C).

The support substrate 102 is etched using the resist pattern 116 as a mask. The individual semiconductor packages 200 are separated by etching until the first groove portion 102c formed by step (a) is reached on the first surface side 102a of the support substrate 102 (FIG. 3D). Through the above process, semiconductor packages 200 that have the same structure as the semiconductor packages 100 shown in FIG. 1 may be produced.

The manufacturing method of the semiconductor package 200 according to the present embodiment was described above. According to the manufacturing method of the semiconductor package 200 according to the present embodiment, instead of using the conventional process of laser dicing, the semiconductor packages are separated by a combination of a wet etching process and a cutting process that uses a dicing saw. As a result of this method, especially in the manufacturing of small semiconductor packages, production speed improves and cost decreases. Particularly when the support substrate 102 is a metal substrate, the common problem of metal burrs appearing on the cut surface may be prevented, thus producing a high-quality semiconductor package.

When, for example, separation is performed using only wet etching, it is necessary to have individual etching processes for the insulating resin layer 111 and the support substrate 102. Because of this, lowering the processing speed is a concern, as it is necessary to etch the support substrate en bloc. Further, manufacturing costs increase as different chemicals are needed for each etching process.

Conversely, when separation is done by cutting the insulating resin layer 111 and the support substrate 102 at the same time using a dicing saw, for example, a lower throughput of the semiconductor packages due to the common problem of metal burrs is a concern. Further, since the support substrate is cut en bloc, the dicing blade wears out faster, which increases manufacturing costs.

According to the present embodiment, since separation is performed by combining a wet etching process and a cutting process using a dicing saw, the problems mentioned above do not occur, thus lowering manufacturing costs and increasing production speed.

### Embodiment 3

### [Manufacturing Method of Semiconductor Package 300]

The manufacturing method of the semiconductor package 300 according to the present embodiment will be described while referencing the drawings. As the structure of the semiconductor package 300 according to the present embodiment is the same as the structure of the semiconductor package 100 in embodiment 1, a description is omitted.

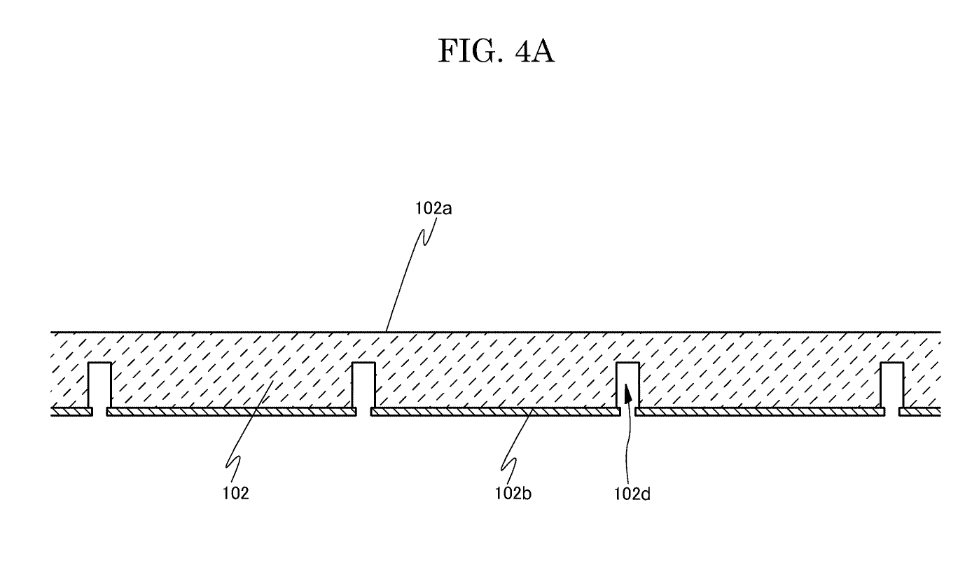

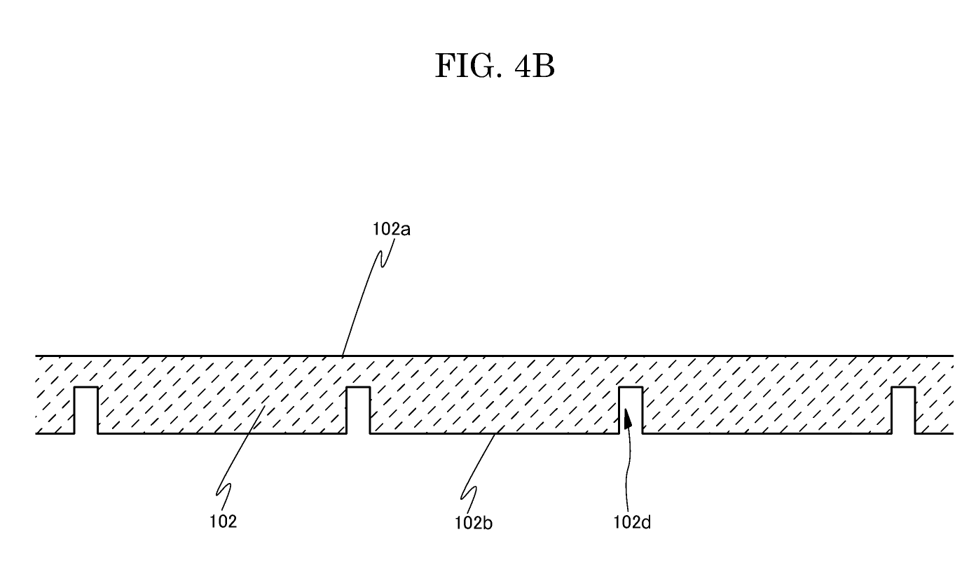

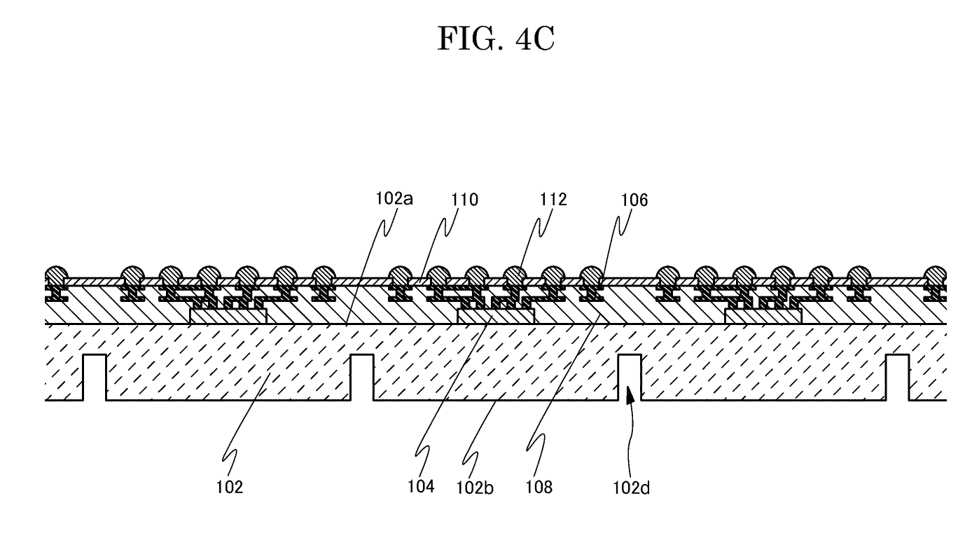

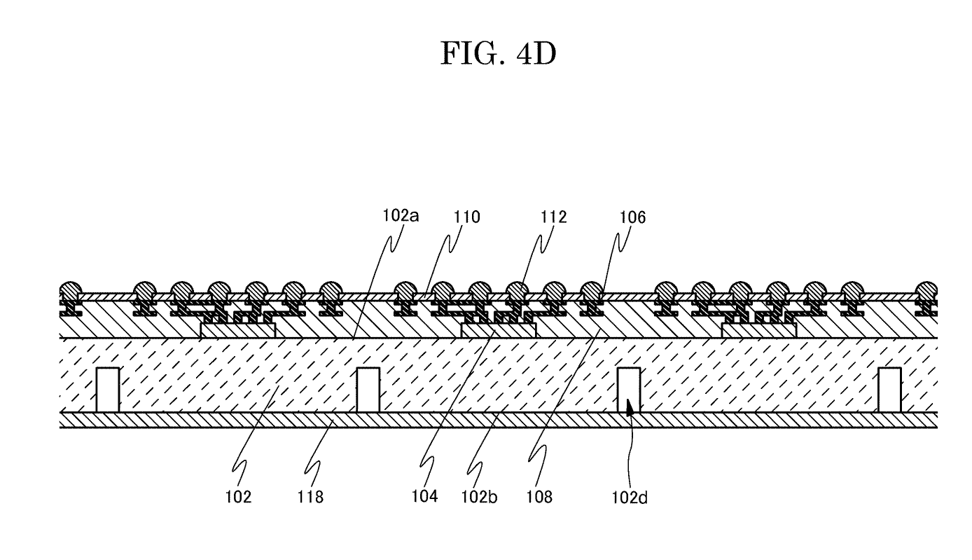

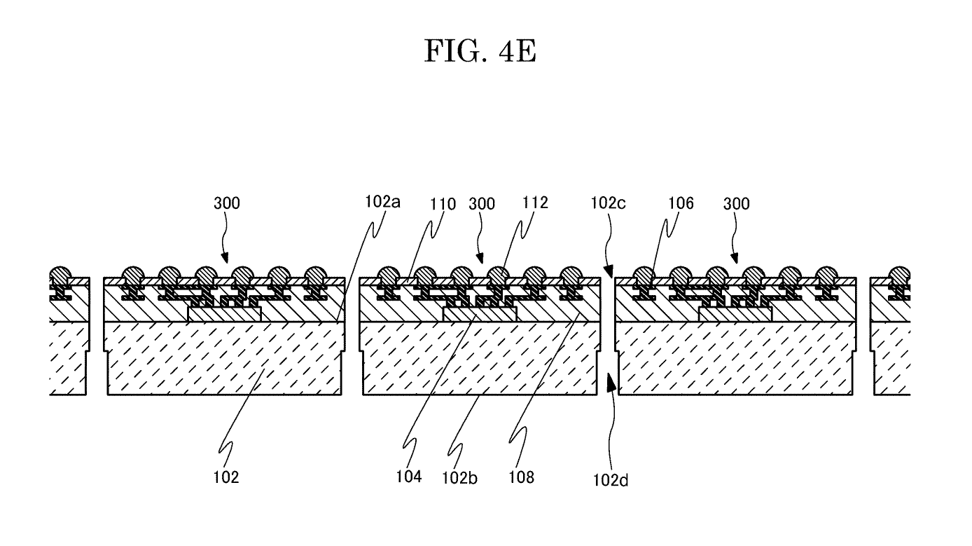

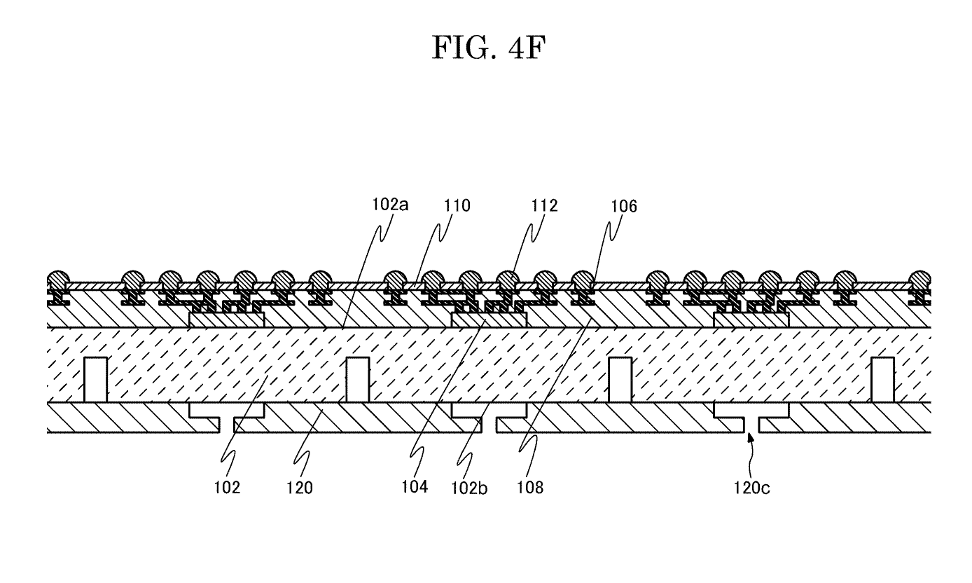

FIG. 4A through 4E are cross-sectional views describing the manufacturing method of the semiconductor package 300 according to the present embodiment.

In the present embodiment, first, the second groove portion having a bottom is formed on the second surface on the opposite side of the first surface in the areas between the plurality of semiconductor devices arranged at intervals on the first surface side of the support substrate.

In the present embodiment, the resist pattern 116 is formed by photolithography on the second surface side 102b of the support substrate 102. This resist pattern 116 is used as a mask to etch the support substrate 102 by wet etching. The second groove portion 102d having a bottom is formed without etching as far as the first surface 102a of the support substrate 102 (FIG. 4A). The depth of the second groove portion 102d from the second surface 102b of the support substrate is preferably about ⅔ of the thickness of the support substrate 102. In the present embodiment, the thickness of the support substrate is 300 μm, therefore about 200 μm is preferably etched leaving about 100 μm of the support substrate 102 from the second surface 102a.

If the second groove portion 102d having a bottom is deeper than this, the etching time is prolonged and productivity worsens. Handling problems also occur. If the second groove portion 102d having a bottom is shallower than this, the dicing blade wears out faster and manufacturing costs increase.

The formation of the second groove portion 102d is not limited to an etching process, and may also be formed by a cutting process using a dicing blade.

After the second surface side 102b of the support substrate 102 has been etched, the resist mask 116 is removed (FIG. 4B).

Next, from the state shown in FIG. 4B, the semiconductor device 104, wiring 106, insulating resin layer 111, and solder balls 112 are formed on the second surface side 102b of the support substrate 102 (FIG. 4C). The steps described above may be used for these steps.

Next, step (a) takes place. Namely, cutting is performed from the first surface side, and a first groove portion 102c is formed penetrating the insulating resin layer 111 and exposing the support substrate.

In the present embodiment, after the second surface 102b of the support substrate is etched (step (b)), and before step (a), a support member is placed on the second surface side 102b of the support substrate 102. In the present embodiment, dicing tape 118 is used as the support member and is applied to the second surface side 102b (FIG. 4D).

Since the second groove portion 102d having a bottom is formed on the support substrate 102 by the previously described process, the structure shown in FIG. 4C is not mechanically strong. Accordingly, the support substrate 102 is held in place by the support member during the dicing process, as in the present embodiment.

In this state, the insulating resin layer 111 and the remaining portion of the support substrate 102 are cut with a dicing blade at the same time. Cutting is performed by rotating the dicing blade at high speed while cooling and washing away cutting waste with purified water. In this way, individual semiconductor packages 300 are separated (FIG. 4E). Semiconductor packages 300 having the same structure as the semiconductor packages 100 shown in FIG. 1 are produced by the process described above.

The manufacturing method of the semiconductor package 300 was described above. According to the manufacturing method of the semiconductor package 300 according to the present embodiment, instead of using the conventional process of laser dicing, the semiconductor packages are separated by a combination of a wet etching process and a cutting process that uses a dicing saw. As a result of this method, especially in the manufacturing of small semiconductor packages, production speed improves and costs decrease. Particularly when the support substrate 102 is a metal substrate, the common problem of metal burrs appearing on the cut surface may be prevented, thus producing a high-quality semiconductor package.

When, for example, separation is performed using only wet etching, it is necessary to have individual etching processes for the insulating resin layer 111 and the support substrate 102. Because of this, lowering the processing speed is a concern, as it is necessary to etch the support substrate en bloc. Further, manufacturing costs increase as different chemicals are needed for each etching process.

Conversely, when separation is done by cutting the insulating resin layer 111 and the support substrate 102 at the same time using a dicing saw, for example, a lower throughput of the semiconductor packages due to the common problem of metal burrs is a concern. Further, since the support substrate is cut en bloc, the dicing blade wears out faster, which increases manufacturing costs.

According to the present embodiment, since separation is performed by combining a wet etching process and a cutting process using a dicing saw, the problems mentioned above do not occur, thus lowering manufacturing costs and increasing production speed.

### Modification Example 2

As is shown in FIG. 4F, in a modification example of the manufacturing method of the semiconductor package 300 according to the present embodiment, a dicing jig 120 may be used instead of the dicing tape 118 shown if FIG. 4E. In the dicing jig, an adsorption hole 120c is provided in a position corresponding to each of the semiconductor packages 300 being separated. The support substrate 102 is held steady by vacuuming from the adsorption holes 120c, and step (a) may take place.

The manufacturing method of a semiconductor package in preferable embodiments according to the present invention were described above. However, these are merely exemplary, and do not limit the technical scope of the invention in any way. Naturally, a person skilled in the art may be able to make various modifications without deviating from the substance of the invention described in the scope of the patent claims. Therefore, it should be understood that such modifications are naturally included in technical scope of the present invention.

1. A method for manufacturing a semiconductor package, comprising:
arranging a plurality of semiconductor devices at intervals on a first surface side of a support substrate,
forming an insulating resin layer forming a wiring connecting to each of the plurality of semiconductor devices and embeds the plurality of semiconductor devices,
cutting from the first surface side in a areas between the plurality of semiconductor devices, forming a first groove portion penetrating the insulating resin layer exposing the support substrate, and separating the individual semiconductor packages by forming a resist pattern having openings arranged corresponding to the first groove portion on a second surface on the opposite side of the first surface, etching the openings from the second surface side, and forming a second groove portion on the second surface side.

2. The method for manufacturing a semiconductor package according to claim 1, wherein the etching process is a wet etching process.

3. The method for manufacturing a semiconductor package according to claim 1, wherein the cutting process uses a dicing blade to cut the insulating resin layer as well as the support substrate.

4. The method for manufacturing a semiconductor package according to claim 3, wherein cutting is performed using a dicing blade, after the second surface is etched, a support member is put in place, and the insulating resin layer and a portion of the support substrate are cut at the same time.

5. The method for manufacturing a semiconductor package according to claim 4, wherein the support member is either dicing tape or a dicing jig.

6. The method for manufacturing a semiconductor package according to claim 1, wherein the support substrate is a metal substrate, and an organic resin is used to form the organic resin layer.

7. The method for manufacturing a semiconductor package according to claim 1, wherein the order of the mechanical cutting process and the chemical etching process is arbitrary.

8. The method for manufacturing a semiconductor package according to claim 1, wherein the width of the second groove portion is wider than the width of the first groove portion.

9. A method for manufacturing a semiconductor package comprising:
forming a bottom groove portion on a second surface on the opposite side of a first surface in areas between a plurality of semiconductor devices arranged at intervals on the first surface side of a support substrate,
arranging a plurality of semiconductor devices at intervals on the first surface side of the support substrate,
forming an insulating resin layer forming a wiring connecting to each of the plurality of semiconductor devices and embeds the plurality of semiconductor devices, and
separating by cutting from the first surface side along a boundary by a mechanical process.

10. The method for manufacturing a semiconductor package according to claim 9, wherein the groove portion is formed either by cutting by etching or cutting with a dicing blade.

11. A semiconductor package, comprising:
a support substrate, and
at least one semiconductor device arranged on a first surface of the support substrate; and
an insulating resin layer arranged to cover the semiconductor devices and connected to at least one semiconductor device on the first surface side;
wherein an end portion of the second surface opposite the first surface is located further inward than an end of the first surface on the support substrate.
